(19) United States
(12) Patent Application Publication
(10) Pub. No.: US 2025/0169376 A1
(43) Pub. Date: May 22, 2025

(54) Josephson Junction Device and Method of Manufacture Thereof

(71) Applicant: Samsung Electronics Co., Ltd., Suwon-si (KR)

(72) Inventors: Jaehyeong LEE, Suwon-si (KR); Hyeokshin KWON, Suwon-si (KR); Daeyun KIM, Suwon-si (KR); Daeseok HAN, Suwon-si (KR)

(73) Assignee: Samsung Electronics Co., Ltd., Suwon-si (KR)

(21) Appl. No.: 18/664,982

(22) Filed: May 15, 2024

(30) Foreign Application Priority Data
Nov. 20, 2023 (KR) 10-2023-0161446

(51) Int. Cl. H10N 60/01; H10N 60/12; H10N 60/85

(52) U.S. Cl. CPC H10N 60/0912; H10N 60/12; H10N 60/85

(57) ABSTRACT

A Josephson junction device has a second region between first and third regions, and the Josephson junction device includes: a substrate in the first, second, and third regions; a first superconductive layer arranged on the substrate in the first and second regions and not the third region; a second superconductive layer arranged in the second and third regions and spatially overlapping the first superconductive layer in the second region; an oxide layer sandwiched between the first superconductive layer the second superconductive in the second region; and a first trench in the substrate in the third region, the trench passing under the second superconductive layer in the third region.

### CROSS-REFERENCE TO RELATED APPLICATIONS

This application is based on and claims priority under 35 U.S.C. § 119 to Korean Patent Application No. 10-2023-0161446, filed on Nov. 20, 2023, in the Korean Intellectual Property Office, the disclosure of which is incorporated by reference herein in its entirety.

### BACKGROUND

### 1. Field

The present disclosure relates to a Josephson junction device and a method of manufacturing the Josephson junction device.

### 2. Description of Related Art

A quantum bit, or qubit, is a basic information unit used by a quantum computer. The term “qubit” and the like may also mean an actual physical device used to store information in quantum computers or a unit of information extracted from an actual physical device. The meaning of the term “qubit” is usually understood from the context of its use.

Physical qubits may be implemented in various ways, for example, as photon qubits, ion trap qubits, topology qubits, superconductive qubits, and the like. Superconductive qubits use a Josephson junction device. A Josephson junction device has a thin insulator thin film arranged between two superconductors. Current designs and techniques for producing Josephson junctions may produce a processing unit with up to several hundred superconductive qubits. However, tens of thousands of superconductive qubits on a processing unit might be needed for practical application.

### SUMMARY

According to the present disclosure, a method of manufacturing a Josephson junction device with improved yield may be provided.

Additional aspects will be set forth in part in the description which follows and, in part, will be apparent from the description, or may be learned by practice of the presented embodiments of the disclosure.

According to an aspect of an embodiment, a Josephson junction device has a second region between first and third regions, and the Josephson junction device includes: a substrate in the first, second, and third regions; a first superconductive layer arranged on the substrate in the first and second regions and not the third region; a second superconductive layer arranged in the second and third regions and spatially overlapping the first superconductive layer in the second region; an oxide layer sandwiched between the first superconductive layer the second superconductive in the second region; and a first trench in the substrate in the third region, the trench passing under the second superconductive layer in the third region.

In between the first region and the second region there may be a step in the substrate.

The first region may have the first superconductive layer therein, but not the oxide layer and the second superconductive layer.

The third region may have the second superconductive layer therein, but not the first superconductive layer and the oxide layer.

Each of the first superconductive layer and the second superconductive layer independently may include aluminum (Al), neobium (Nb), indium (In), alpha-tantalum (α-Ta), titanium (Ti), lead (Pb), vanadium (V), or a compound thereof.

The oxide layer may include aluminum oxide, neobium oxide, or alpha-tantalum (α-Ta) oxide.

In another general aspect, there is a method of manufacturing a Josephson junction device having a substrate in a first region, a third region, and a second region between the first and second regions, and the method includes: in the first, second, and third regions, forming a first superconductive layer on the substrate; in the first, second, and third regions, forming an oxide layer on the first superconductive layer; in the first, second, and third regions, forming a second superconductive layer on the oxide layer; in the first region, performing an etching process to remove the oxide layer and the second superconductive layer therein while maintaining at least some of the first superconductive layer therein; forming a mask on the first superconductive layer in the first region and on the second superconductive layer in the second and third regions; and, using the mask, removing, by the etching process, from the third region, the first superconductive layer and the oxide layer.

The etching process in the third region may reduce the second superconductive layer in the third region.

The etching process in the third region may form a trench in the substrate in the third region.

The etching process may include anisotropic etching in a first direction and anisotropic etching in a second direction.

The anisotropic etching in the first direction may remove a first side of the first conductive layer and the oxide layer in the third region, and the anisotropic etching in the second direction may remove a second side of the first conductive layer and the oxide layer in the third region.

The etching process may include plasma etching, reactive ion etching, or ion milling.

The mask may be composed of a silicon oxide mask, a gallium mask, a chromium mask, or an e-beam mask, wherein, in the third region, a strip of the mask on the second superconductive layer may separate two holes in the mask that allow the etching process, and wherein the holes may allow the etching process to remove the first superconductive layer and the oxide layer from the third region.

After the etching process, the mask may be removed a portion of the Josephson junction device where the mask has been removed may be cleaned.

The mask may not cover a portion of the third region.

Each of the first superconductive layer and the second superconductive layer independently may include aluminum (Al), iobium (Nb), indium (In), alpha-tantalum (α-Ta), titanium (Ti), lead (Pb), vanadium (V), or a compound thereof.

In yet another aspect, there is a method of producing a Josephson junction device having a second region between first and third regions, the method includes: in first, second, and third regions, forming a first superconductive layer on a substrate; in at least the second and third regions, forming an oxide layer on the first superconductive layer and forming a second superconductive layer on the oxide layer; forming a mask covering the second region and only parts of the third region; and performing an etching process that removes the first superconductive layer and the oxide layer from the third region while preserving at least some of the second superconductive layer in the third region.

The etching process may include dry anisotropic etching performed at two different angles relative to a plane of the substrate.

The etching process may include dry isotropic etching.

The method may further include: in the first region, forming the oxide layer and the second superconducting layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates an overhead view of a configuration of a Josephson junction device and a superconductive qubit including the same, according to one or more embodiments;

FIG. 2A illustrates an overhead view of detail of the Josephson junction device in FIG. 1, according to one or more embodiments;

FIG. 2B illustrates a cross-sectional view of FIG. 2A, according one or more embodiments.

FIG. 3 is a cross-sectional view taken along line A-A′ (first region S1) of the Josephson junction device of FIGS. 2A and 2B;

FIG. 4 is a cross-sectional view taken along line B-B′ (second region S2) of the Josephson junction device of FIGS. 2A and 2B;

FIG. 5 is a cross-sectional view taken along line C-C′ (third region S3) of the Josephson junction device of FIGS. 2A and 2B;

FIGS. 6A to 6F are views illustrate a general method of manufacturing a Josephson junction device, according to one or more embodiments;

FIGS. 7A and 7C are cross-sectional views taken along lines A1-A1′ (first region S1) of FIGS. 6D to 6F, respectively;

FIGS. 8A to 8C are cross-sectional views taken along lines B1-B1′ (second region S2) of FIGS. 6D to 6F, respectively;

FIGS. 9A to 9C are cross-sectional views taken along lines C1-C1′ (third region S3) of FIGS. 6D to 6F, respectively;

FIGS. 10A and 10B are views illustrating a portion of a method of manufacturing a Josephson junction device according to another embodiment;

FIGS. 11A to 11D are cross-sectional views taken along lines A2-A2′ of FIGS. 10A and 10B;

FIGS. 12A to 12D are cross-sectional views taken along lines B2-B2′ of FIGS. 10A and 10B; and

FIGS. 13A to 13D are cross-sectional views taken along lines C2-C2′ of FIGS. 10A and 10B.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

As noted in the Background, it may be desirable to provide a quantum processing apparatus with thousands of superconductive qubits. However, for superconductive qubits, the instability of the thin insulator film deposition may be a limiting factor with respect to increasing the number of superconductive qubits in a quantum processor.

Regarding the thin insulator film, a superconducting qubit is generally divided into a superconducting transmon part and other superconducting control and signal output parts. Of these parts, the superconducting transmon part may include a shunt capacitor and a Josephson junction. During operation, the superconducting control part may mix the frequency corresponding to the qubit frequency (the resonant frequency of the transmon part) and a specific type of pulse. This mixture of pulses and frequencies is called a qubit gate signal. Increasing the reliability of qubit operations computed by the gate signal operated in this way generally increases the reliability of the qubit's coherence time. In addition, when switching to multiple qubits, the closer the multi-qubit operation is to the target qubit frequency, including coherence time, the more reliable the multi-qubit operation becomes. The main elements of qubit frequencies include the magnitude of the shunt capacitance, the substrate material, and the resistance value of the Josephson junction. All other things being equal, the resistance values of the Josephson junction are determined by the superconductivity of the superconducting electrode that is used, the tunnel thin film material between the superconducting layers, and the thickness and area.

To elaborate on the tunnel thin film issue, consider that for Josephson junction devices, which are typically manufactured on superconducting qubits, the main production method is a Dolan bridge or a Manhattan-bridge. E-beam lithography is used to form a fine pattern (around ˜100 nm) through double layer coating and an under-cut at the bottom of the boundary of the pattern. As a result, the error of the patterning itself is within a few nm compared to the target size (several percent).

The superconducting electrode material used in the pattern produced as mentioned above is mainly aluminum, which may involve using tunnel bonding using the oxide film of the aluminum. For this purpose, the angle of the sample holder must be adjustable in the oxidation chamber without breaking the vacuum. In the case of the aluminum oxide film, such film is typically in the form of AlxOy. The aluminum oxide film structure varies depending on the oxidation conditions such as the pressure, exposure time, and the condition of the chamber. In general, after a thickness of around 2 A is manufactured, additional aging may occur depending on the type of treatment, and as a result, the error compared to the target thickness is at least a few percent. Even within the same wafer or chip, there is usually an error of about 1˜2%.

In addition, angle tilting deposition of metal electrodes is usually needed for in-situ oxidation. Usually, the main E-beam evaporator is used, and the method of deposition of thin films on samples with this undermines uniformity within the same chip and wafer. Although it varies with the equipment, the size deviation is about 10% based on a 8-inch wafer (due to the size if the wafer).

Furthermore, the thickness and area of the tunnel thin film are related; if the thickness is increased, the area should be widened, and if the thickness is decreased, the area should be narrowed. The area part is a noise enhancing/increasing factor (this is sometimes called the Two-Level System). On the other hand, if the area is lowered to reduce this noise source, the thickness decreases, which increases the relative process error and device instability.

Finally, for a deposition method using E-beam resist, only the Josephson junction element must be left by lift-off, which is a factor that lowers yield such as re-deposition of residue and damage during lift-off. Yield reduction may be around 5%.

Overall, the lower the deviation in the target qubit frequency the better. With state of the art technology, a deviation of 14 MHz at 5.74 GHz can be possible, which is around 0.24% deviation. However, for more than 1,000 qubits, a deviation of 6 MHz or lower appears to be called for, in which case the deviation should be reduced to 0.1% or less. Without introducing changes in materials and processing methods, where the instability of each patterning, oxide composition, and metal film deposition is confined to aluminum according to current process techniques, at the current level, this has limitations. Among them, the instability of oxide film is a factor whose improvement would increase the number of qubits.

Hereinafter, a Josephson junction device and a method of manufacturing the Josephson junction device will be described in detail with reference to the accompanying drawings. In the following drawings, the same or like reference numerals refer to the same or like components, and the size and/or proportions of each component in the drawings may be exaggerated for clarity and convenience of description. In addition, embodiments described below are merely illustrative, and various modifications are possible from these embodiments.

Hereinafter, the term “upper portion” or “on” may also include “to be present above on a non-contact basis” as well as “to be on the top portion in directly contact with”. The singular expression includes plural expressions unless the context clearly implies otherwise. In addition, when a part “includes” a component, this means that it may further include other components, not excluding other components unless specifically stated to the contrary.

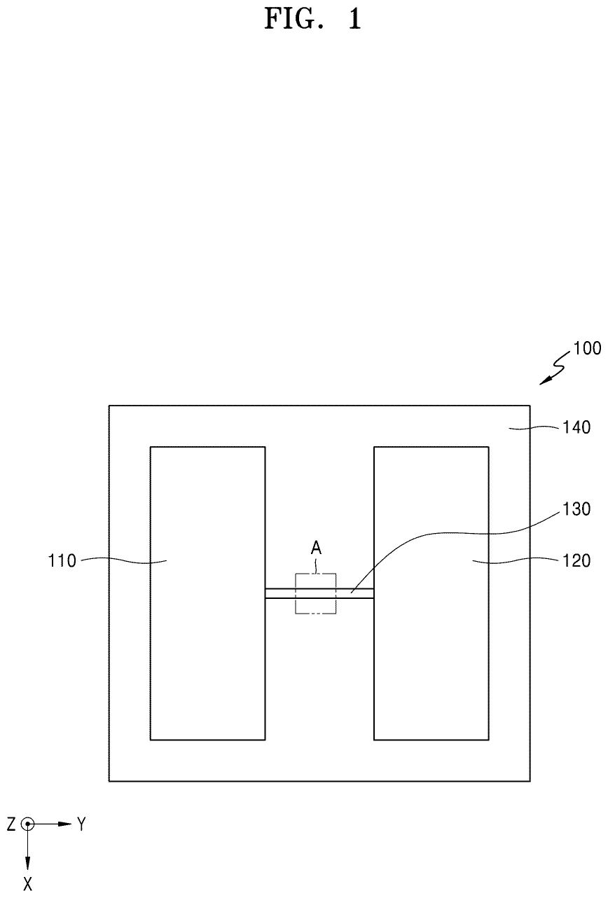

FIG. 1 illustrates a configuration of a Josephson junction device and a superconductive qubit including the same, according to one or more embodiments. A ratio of a size between (and of) components shown in the drawings below may be exaggerated for explanation.

Referring to FIG. 1, a superconductive qubit 100 may include a substrate 140, a first pad 110 and a second pad 120 provided adjacent to each other on the substrate 140, and a Josephson junction device 130 provided between the first pad 110 and the second pad 120 on the substrate 140. The superconductive qubit 100 may be a transmon qubit. The transmon qubit may be designed to have a high ratio of Josephson energy to charge energy to lower sensitivity to charge noise. As used herein, “superconductive”, “superconductor”, and the like do not necessarily imply the relevant material or element is in a superconductive state. For example, some materials may only superconduct when at a sufficiently low temperature. Therefore, “superconductive” and the like refer to materials/elements that are capable of superconductivity when the device including same (e.g., a superconductive qubit) is in an operable state.

The first pad 110 and the second pad 120 may serve as antennas for transmitting electromagnetic signals to the Josephson junction device 130 and receiving electromagnetic signals from the Josephson junction device 130. The first pad 110 and the second pad 120 may include a superconductive material. For example, the first pad 110 and the second pad 120 may include aluminum (Al), neobium (Nb), indium (In), alpha-tantalum (α-Ta), titanium (Ti), lead (Pb), vanadium (V), or a compound thereof, and for example, may include NbN, NbTiN, TiN, or VN.

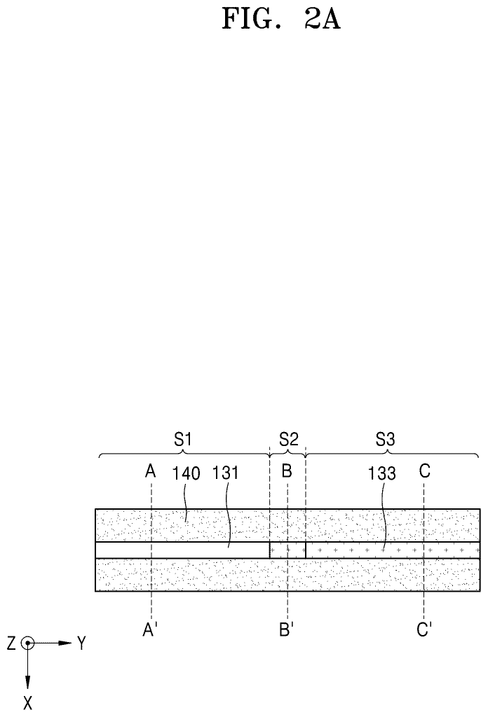

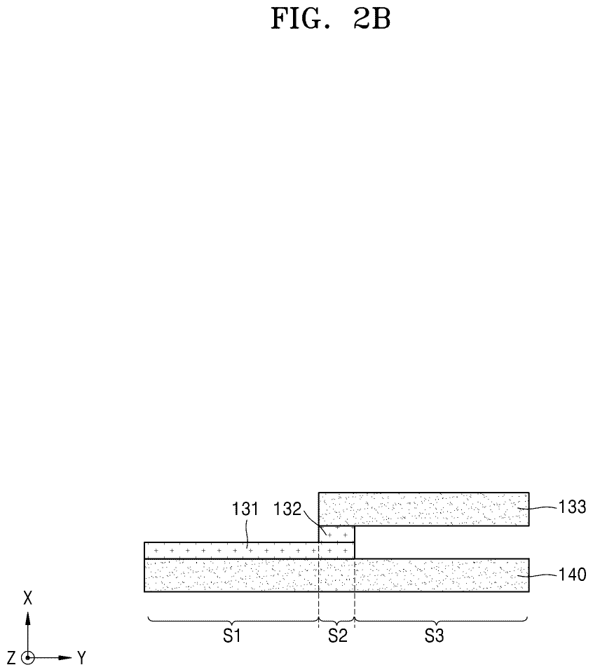

FIG. 1 shows X-Y-Z directions. The dot of the Z direction symbolizes a normal of X and Y that comes up from the page of the figure. The first pad 110 may be arranged lengthwise in a first direction (the X direction) and may be electrically connected to a first superconductive layer 131 of FIGS. 2A and 2B, described later. For example, the first pad 110 may be composed of a same material as the first superconductive layer 131 of FIGS. 2A and 2B. The second pad 120 may also be arranged lengthwise in the first direction, and may be electrically connected to a second superconductive layer 133 (see FIGS. 2A and 2B), described later. For example, the second pad 120 may be composed of the same material as the second superconductive layer 133 of FIGS. 2A and 2B.

The substrate 140 may be a silicon substrate or a silicon on insulator (SOI) substrate, but is not limited thereto, and various other materials capable of manufacturing the superconductive qubit 100 by a semiconductor process may be used in the substrate 140.

As described herein, the Josephson junction 130 may be a strip-like structure with various layers (vertically) at different regions thereof (see regions S1, S2, and S3 in FIGS. 2A and 2B, and other FIGS.). In addition, the Josephson junction 130 may include various structural features of the substrate 140 near the Josephson junction 130, which may vary at the different regions. For example, there may be trenches beside (region S1) or beside-and-under (region S3) the strip of the Josephson junction 130.

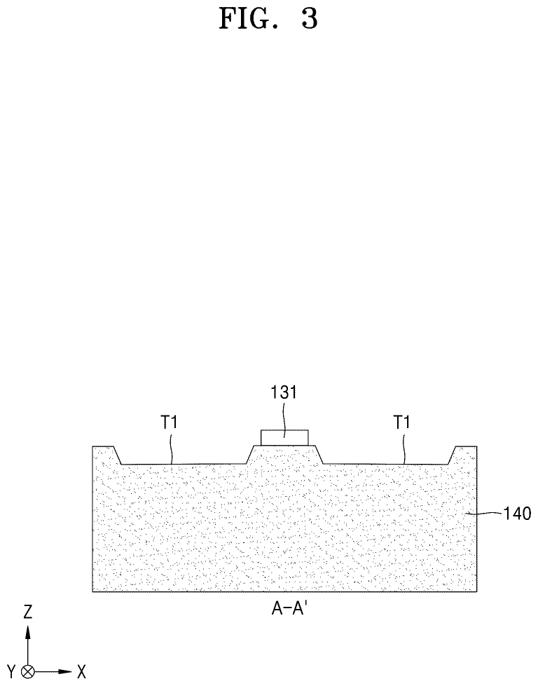

FIG. 2A illustrates detail of the Josephson junction device, according to one or more embodiments. FIG. 2A is an enlarged view of portion A annotated in FIG. 1 (center). FIG. 2B illustrates a cross-sectional view of FIG. 2A. FIGS. 3-5 show cross-sectional views of regions S1, S2, and S3, respectively. The Josephson Junction device of FIGS. 2-5 may be produced with different etching techniques (e.g., isotropic or anisotropic).

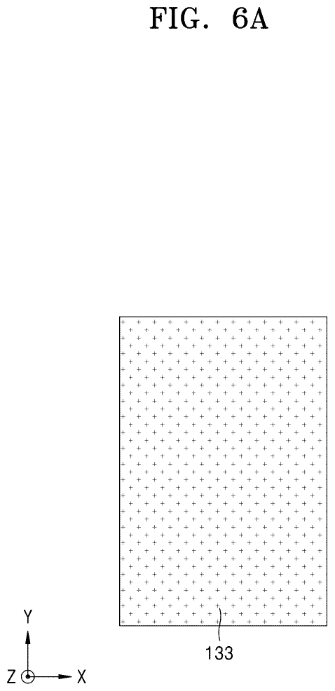

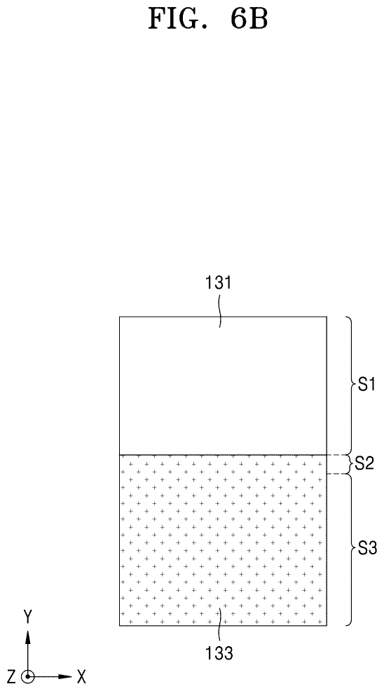

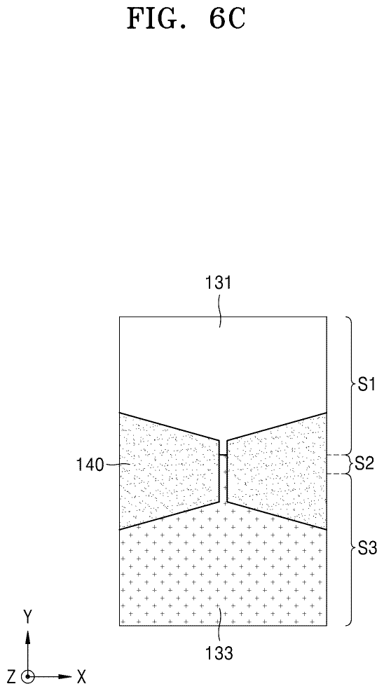

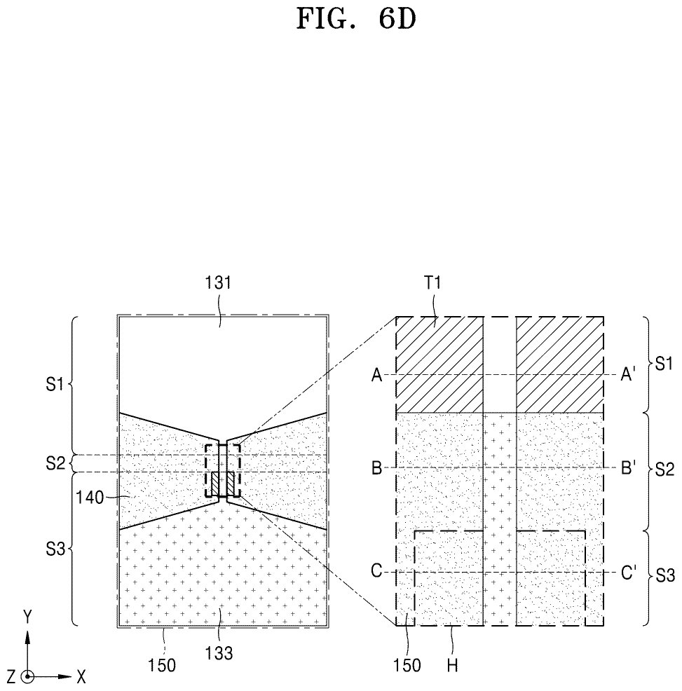

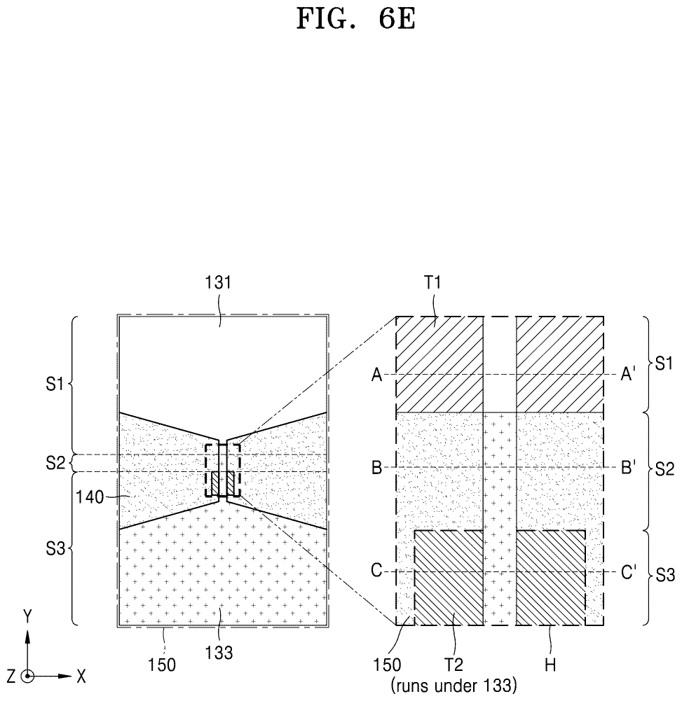

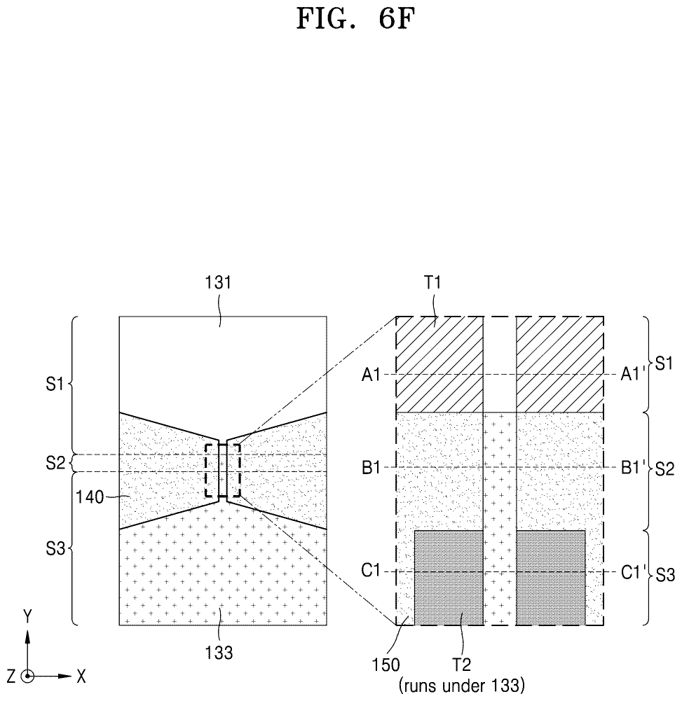

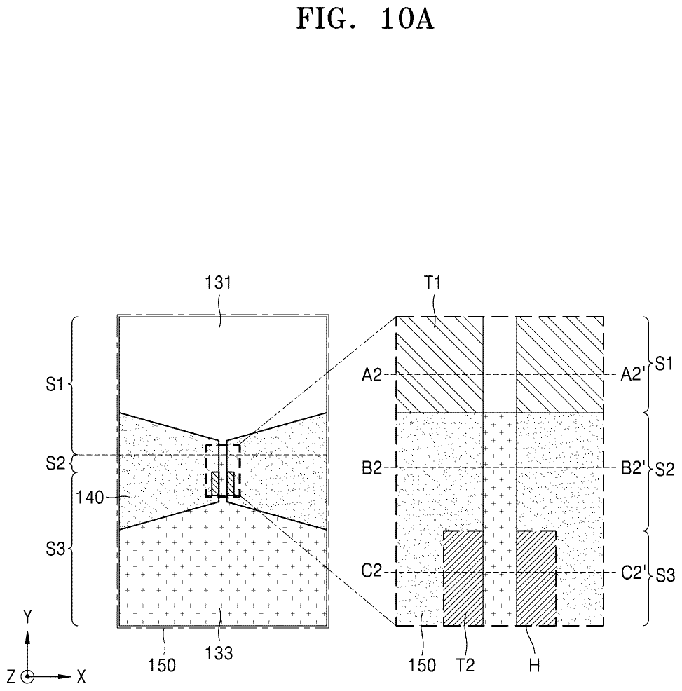

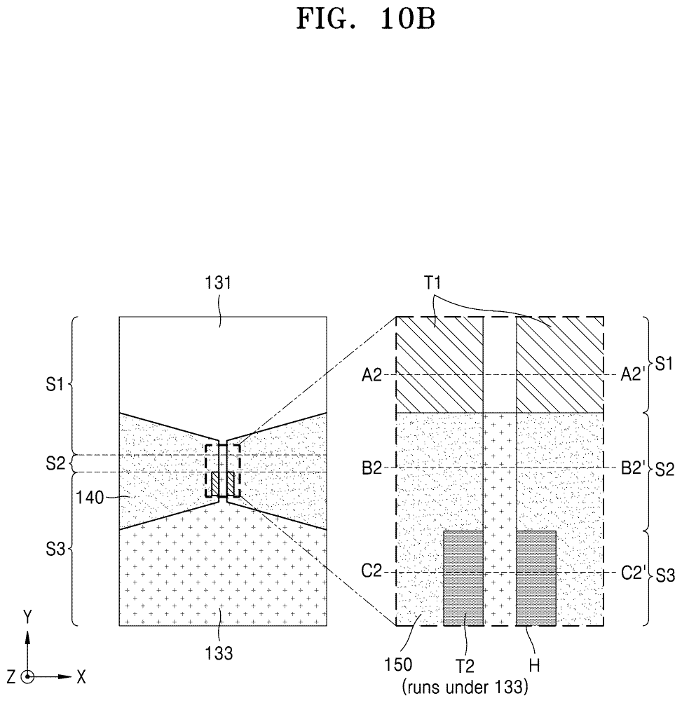

For understanding, FIG. 2A includes annotation lines A-A′, B-B′, and C-C′. Other Figures show cross-sectional views at these annotation lines. For example, FIGS. 3, 4, and 5 show cross-sectional views of annotation lines A-A′, B-B′, and C-C′, which respectively correspond to, respectively. FIG. 2A also includes annotations for regions S1, S2, and S3 (sometimes referred to as first, second, and third regions). See FIGS. 6B-6F, 10A, and 10B for the same annotations.

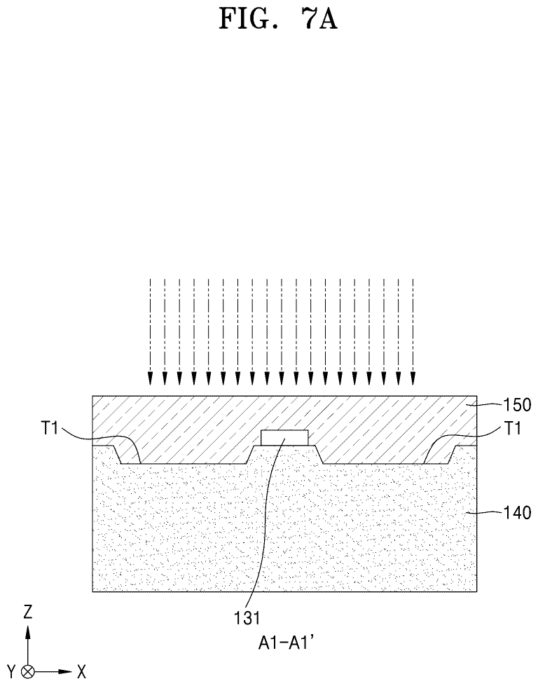

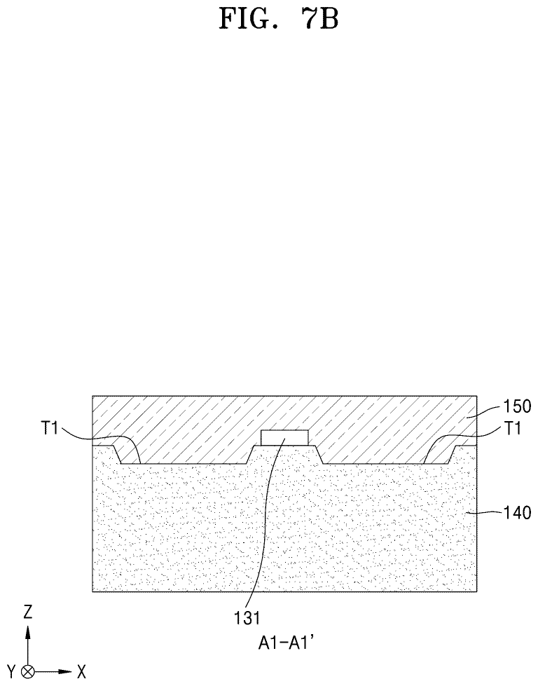

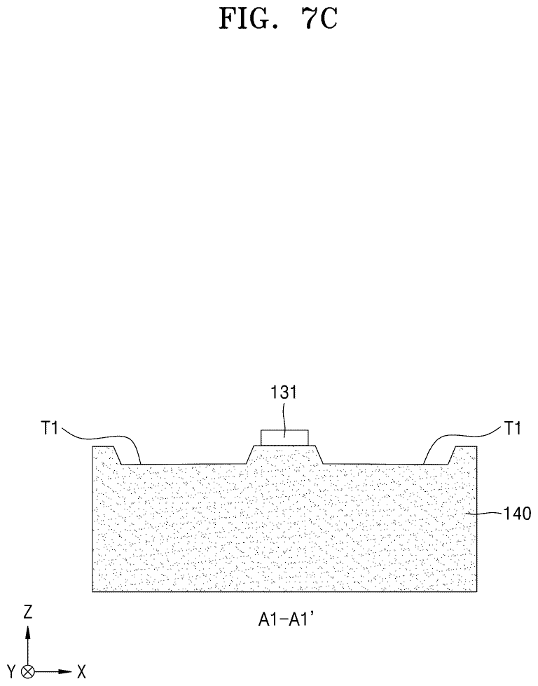

For further understanding, FIGS. 2A-5 show the Josephson junction 130, according to one or more embodiments, after etching, as described with reference to FIGS. 7A-9F.

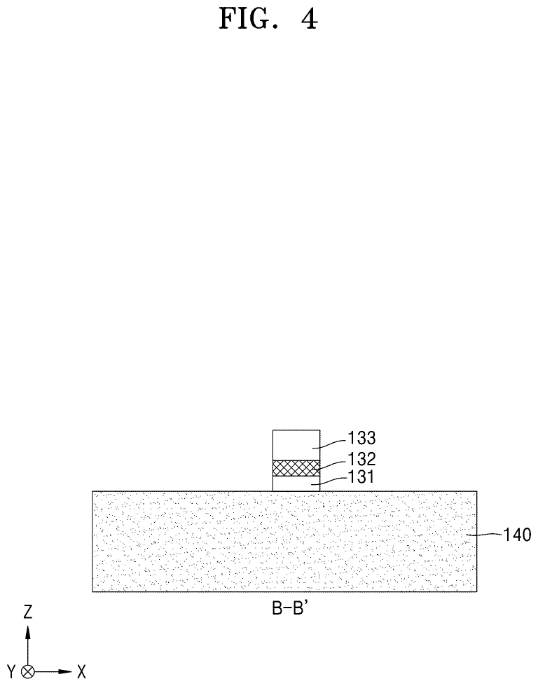

Referring to FIG. 2A, the Josephson junction device 130 may include a first superconductive layer 131 arranged lengthwise in the second direction (i.e., the Y direction) in regions S1 and S2, a second superconductive layer 133 also arranged lengthwise in the second direction and arranged in regions S2 and S3 to partially overlap (discussed next) the first superconductive layer 131, and an oxide layer 132 (shown in FIG. 4 and others) arranged in region S2 to face a portion of an upper surface of the first superconductive layer 131 and a portion of a lower surface of the second superconductive layer 133. Inward end-areas of the first and second superconductive layers 131, 133 may overlap at region S2, with the right end of superconductive layer 131 (not shown) being at the right edge of region S2 and the left end of superconductive layer 133 being at the left edge of region S2.

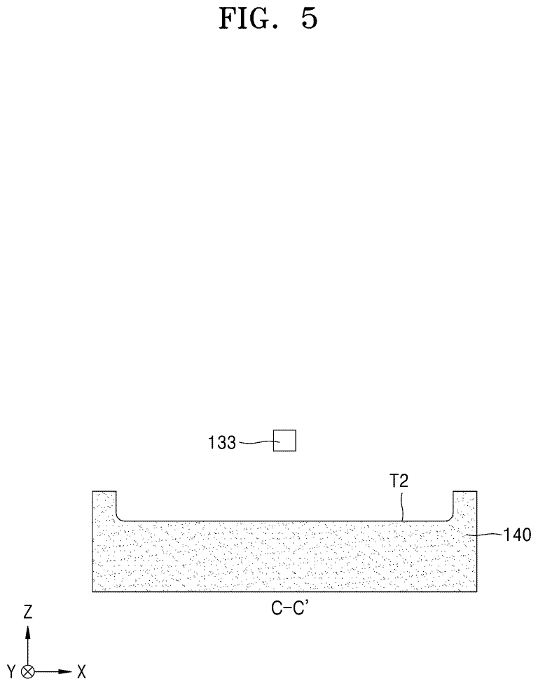

To elaborate, the superconductive layer 131, the oxide layer 132, and the superconductive layer 133 may have lengthwise extents for different regions. The first superconductive layer 131 may run only through regions S1 and S2 (see FIGS. 3 and 4). The oxide layer 132 may be only at region S2 (see FIG. 4). Region S2 may be thought of as corresponding to the “junction” of the Josephson junction device 130. The second superconductive layer 133 ray run only through regions S2 and S3 (see FIGS. 4 and 5). The oxide layer 132 may function as the non-conductive thin film insulator of the Josephson junction device 130.

In addition, the shape of the substrate 140 near the strip-like structure may vary at the different regions S1, S2, and S3. At region S1 there may be recesses (trenches) in the substrate 140 next to the strip-like structure and the superconductive layer 131 may reside upon a common/center wall of the recesses/trenches (see FIG. 3). At region S2 the substrate 140 may be flat and the first superconductive layer 131 (having layers above it) may reside upon the substrate 140 (see FIG. 4). At region S3 there may be a single trench/recess in the substrate 140 undercutting the second superconductive layer 133 and allowing the same to span region S3 without contacting the substrate 140.

To further aid understanding, the first superconductive layer 131 may be a horizontal strip, at a given elevation, conductively coupled with the first pad 110 (e.g., contacting it or an extension of it) and extending from the first pad 110 to a region between the first and second pads 110, 120 (e.g. region S2). Similarly, the second superconductive layer 133 may be a horizontal strip, at a given elevation (e.g., lower than the first superconductive layer 133), conductively coupled with the second pad 120 (e.g., contacting it or an extension of it) and extending from the second pad 120 to the region between the first and second pads 110, 120 (e.g. region S2).

The first superconductive layer 131 and the second superconductive layer 133 may be arranged lengthwise in the second direction on/above an upper surface of the substrate 140. As noted above, at region S2, a portion (e.g. end area) of the second superconductive layer 133 may spatially overlap a portion (e.g., end area) of the first superconductive layer 131 in a third direction (i.e., Z direction); at region S2, the oxide layer 132 may be sandwiched between spatially-overlapping end areas of the first and second superconductive layers 131, 133.

The substrate 140 may include portions at the first, second, and third regions S1, S2, and S3. The first superconductive layer 131 may be arranged only on the first and second regions S1 and S2 of the substrate 140, and the second superconductive layer 133 may be arranged only above the second and third regions S2 and S3 of the substrate 140.

The first superconductive layer 131 may be composed of various superconductive thin film materials capable of deposition without requiring patterning (lithography). The first superconductive layer 131 may be composed of, for example, aluminum (Al), neobium (Nb), indium (In), alpha-tantalum (α-Ta), titanium (Ti), lead (Pb), vanadium (V), or a compound thereof, and may include, for example, NbN, NbTiN, TiN, or VN. The first superconductive layer 131 may be deposited to a thickness greater than or equal to, for example, about 100 nm.

Similarly, the second superconductive layer 133 may also be composed of various superconductive thin film materials capable of deposition without requiring patterning (lithography). The second superconductive layer 133 may also include, for example, aluminum (Al), neobium (Nb), indium (In), alpha-tantalum (α-Ta), titanium (Ti), lead (Pb), vanadium (V), or a compound thereof, and may include, for example, NbN, NbTiN, TiN, or VN. The second superconductive layer 133 may be deposited to a thickness greater than or equal to, for example, about 100 nm.

At region S2, the oxide layer 132 may be arranged to cover/contact a part of the upper surface of the first superconductive layer 131 and a lower surface of the second superconductive layer 133. Therefore, the first superconductive layer 131 and the second superconductive layer 133 may not be in direct contact with each other where they overlap. The oxide layer 132 may be composed of, for example, aluminum oxide, neobium oxide, or alpha-tantalum (α-Ta) oxide. However, the oxide layer 132 is not limited thereto.

FIG. 3 is a cross-sectional view taken along line A-A′ of the Josephson junction device of FIG. 2. The cross-section shown in FIG. 3 may be the same for the whole region S1.

Referring to FIG. 3, in region S1, only the first superconductive layer 131 may reside on the substrate 140 in the A-A′ cross-sectional portion of the Josephson junction device 130 (i.e., no oxide layer 132 and no second superconductive layer 133).

First trenches T1 may be formed in the first region S1 of the substrate 140. The first trenches T1 may be formed with the first superconductive layer 131 therebetween. The first trenches T1 may be formed in an operation of etching the second superconductive layer 133 on the first superconductive layer 131 during a process. Due to the first trenches T1 formed in the etching operation, the substrate 140 may not have a uniform thickness in the Y direction, and steps may be formed.

FIG. 4 is a cross-sectional view taken along line B-B′ of the Josephson junction device of FIG. 2. The cross-section shown in FIG. 4 may be the same for the whole region S2.

Referring to FIG. 4, in region S2, the first superconductive layer 131, the oxide layer 132, and the second superconductive layer 133 may reside, in that order, on the substrate 140.

A thickness of the substrate 140 in the B-B′ cross-sectional portion of the Josephson junction device 130 (region S2) may be greater than a thickness of the substrate 140 in the C-C′ cross-sectional portion of the Josephson junction device 130.

FIG. 5 is a cross-sectional view taken along line C-C′ of the Josephson junction device of FIG. 2. The cross-section shown in FIG. 5 may be the same for the whole region S3.

Referring to FIG. 5, in region S3, only the second superconductive layer 133 may reside on (above) the substrate 140 in the C-C′ cross-sectional portion of the Josephson junction device 130. That is, the first superconductive layer 131 and the oxide layer 132 may be absent from region S2.

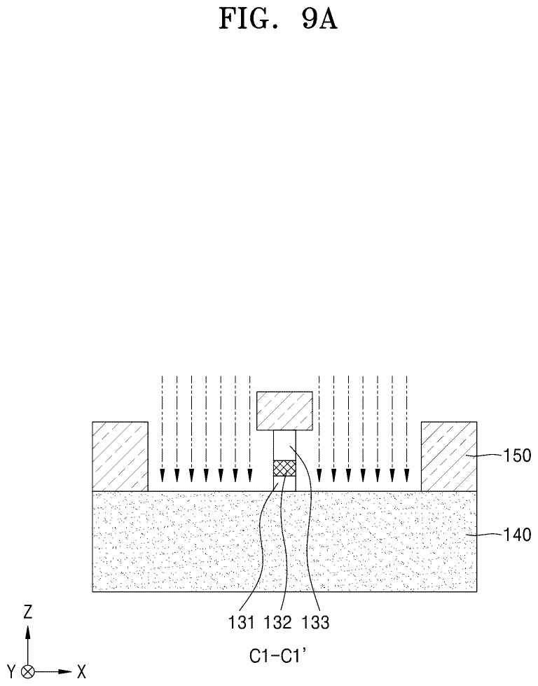

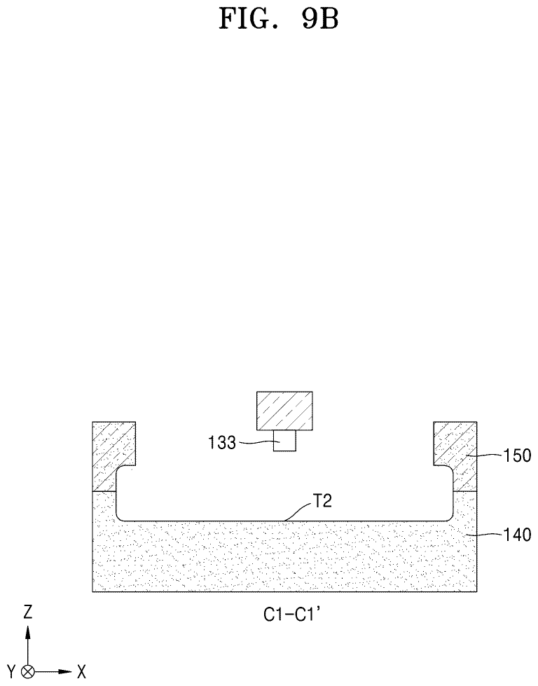

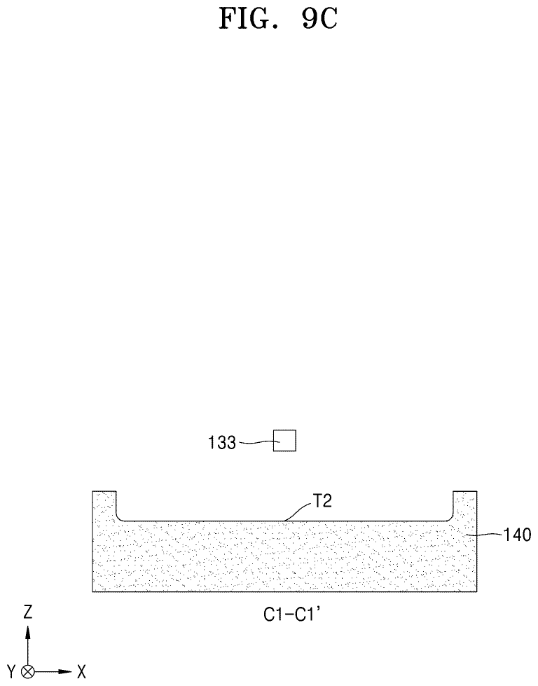

A second trench T2 may be formed in the third region S3 of the substrate 140. The second trench T2 may be formed in an operation of etching away the oxide layer 132 and the second superconductive layer 133 on the first superconductive layer 131 during a production process (see, e.g., FIGS. 9A and 9B). Due to the second trench T2 formed by the etching, the substrate 140 may not have a uniform Y-direction thickness, and a step may be formed at the boundary of regions S2 and S3.

FIGS. 6A to 6F are overhead views illustrating a method of manufacturing a Josephson junction device, according to one or more embodiments. In FIGS. 6A to 6F, the same reference numerals as those in FIGS. 2A-5 denote identical members and regions.

FIGS. 6A to 6F show a workpiece at different stages of a manufacturing method (sequence) using isotropic etching.

Referring to FIG. 6A, the workpiece shown includes all three layers; the second superconductive layer 133 is the top layer and is shown on top as viewed from above (in the Z direction). In the manufacturing sequence, first the first superconductive layer 131 (not shown) is formed onto the substrate 140. The oxide layer 132 (not shown) is then formed onto the upper surface of the first superconductive layer 131. Then, the second superconductive layer 133 is formed onto the oxide layer 132 (also not shown). In short, the production process may produce a strip-like sandwich structure with the oxide layer 132 sandwiched between the first and second oxide layers 131, 133. Such structure may span the regions S1, S2, and S3.

The manufacturing may continue on the workpiece (sandwich structure) shown in FIG. 6A by etching away (or otherwise removing) the second conductive layer 133 and the oxide layer 132 (e.g., at region S1), resulting in the workpiece shown in FIG. 6B.

FIG. 6B shows the workpiece of FIG. 6A after portions of the oxide layer 132 (not shown) and the second superconductive layer 133 are etched away in region S1.

Referring to FIG. 6C, two trapezoidal portions of the substrate 140 are exposed by etching away corresponding portions of the first superconductive layer 131, the oxide layer 132 (not shown), and the second superconductive layer 133. In the etching away of the portions of the first superconductive layer 131, the oxide layer (not shown), and the second superconductive layer 133 in the trapezoidal areas shown in FIG. 6C, steps may occur between the substrate 140 in the first region S1 and the substrate 140 in the second region S2 (see dotted lines) This may be because there is only the first superconductive layer 131 to remove in the region S1 (the trapezoidal portions in that region), whereas portions of the trapezoids in regions S2 and S3 also have the oxide layer 132 and the first superconductive layer 131 to be removed.

FIG. 6D shows a mask 150 applied on upper surfaces of the substrate 140, the first superconductive layer 131, and the second superconductive layer 133 exposed in the Z direction (facing upwards) of the workpiece in FIG. 6C. The mask 150 may have a window (hole H) exposing select portions of substrate 140 and the second superconductive layer 133 in region S3. In FIG. 6D, everything is covered with the mask 150 except for the areas where the holes H are shown (the mask is not depicted in order to show the materials beneath it). The mask 150 may be composed of a silicon oxide mask, a gallium mask, a chromium mask, or an e-beam mask, for example. To summarize, the mask 150 covers all of the workpiece in FIG. 6C except for the holes H.

FIG. 6E shows the workpiece of FIG. 6D after it has been subjected to etching with the mask 150 in place. Referring to FIG. 6E, due to the holes H in the mask 150, under the holes H, portions of the first superconductive layer 131 and the oxide layer 132 underneath the second superconductive layer (and therefore not shown in FIG. 6E) are undercut by etching using the mask 150. The stability of the oxide layer (not shown) may be secured by using dry etching for the etching with the mask 150 in place. As noted, portions of the first superconductive layer 131 and the oxide layer (not shown) that are in in the third region S3 may be etched away (due to being next to the holes H). See FIG. 9B for a cross-sectional view of this etching. In addition, the etching may form a second trench T2 in region S3, under the second superconductive layer and in an area corresponding to the holes H. The second trench T2 is depicted with diagonal lines in FIG. 6E.

In addition to removing the underlying first superconductive layer 131 and the oxide layer 132 (not shown) in region S3, the etching may also remove some of the thickness of the second superconductive layer 133 in region S3. The second superconductive layer 133 may initially have a sufficient thickness to maintain superconductivity despite being thinned in region S3 by being etched. That is, the second superconductive layer 133 may start with sufficient thickness to survive etching.

While etching the portions of the first superconductive layer 131 and the oxide layer 132 (not shown) in region S3, etching of a portion of the substrate 140 may occur. This may be a second trench T2 formed in the third region S3 of the substrate 140 (see FIGS. 9B and 9C for a cross-sectional view of second trench T2).

FIG. 6F shows the workpiece of FIG. 6D after mask removal and cleaning. After the etching operation is completed, the mask 150 is removed. The removal of the mask 150 may be made by an etchant (e.g., a solvent) that reacts only with the mask 150. Additionally, an operation of cleaning the portion where the mask 150 is removed after removing the mask 150 may be further included. Through the cleaning operation, the performance of the Josephson junction device may be improved. The cleaned second trench T2 is depicted by the dark shaded areas of FIG. 6F (right side).

FIGS. 7A-7C, 8A-8C, and 9A-9C show sequences cross-sections of regions S1, S2, and S3, respectively during the etching process discussed above with reference to FIGS. 6D-6F. The etching process may be performed with isotropic etching (e.g., with an etchant). The etching depicted in these figures may all occur at the same time as part of the same etching operation.

FIGS. 7A to 7C show a sequence cross-sectional views taken along lines A1-A1′ (region S1) of FIGS. 6D to 6F, respectively.

FIG. 7A shows the isotropic etching in relation to the first region S1 in a direction perpendicular to the substrate 140. The substrate 140 and the first superconductive layer 131 are not etched due to the mask 150 arranged on the substrate 140 and the first superconductive layer 131. FIG. 7B shows the workpiece after the etching is completed. FIG. 7C shows the workpiece after the isotropic etching is completed and the mask 150 has been removed.

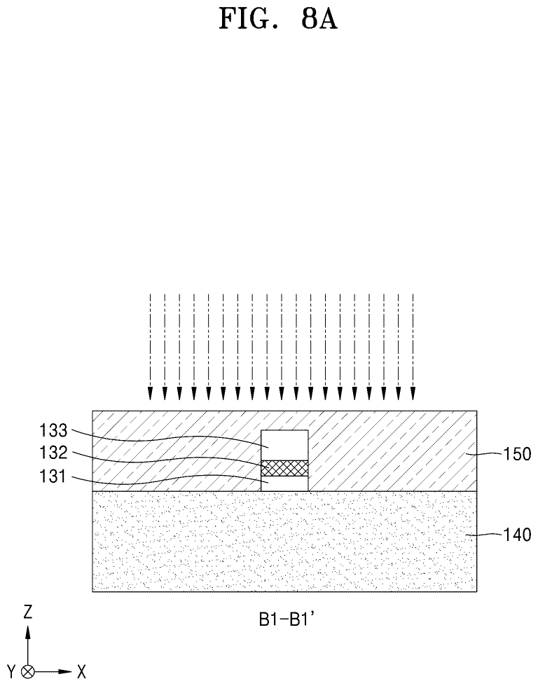

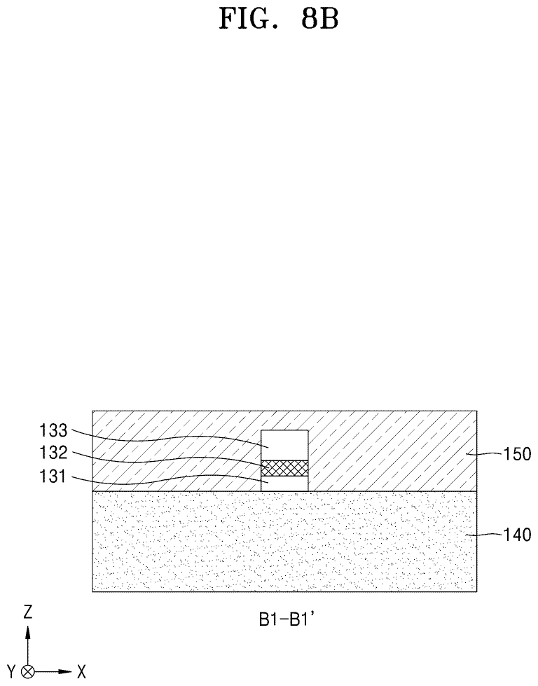

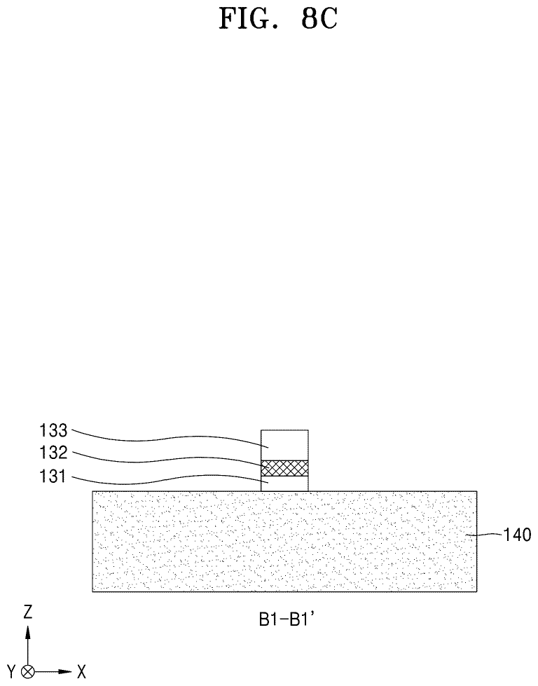

FIGS. 8A to 8C show a sequence of cross-sectional views taken along lines B1-B1′ (second region S2) of FIGS. 6D to 6F, respectively. The second region S2 is masked to preserve the junction/sandwich region.

Referring to FIG. 8A, the isotropic etching in the second region S2. As shown in FIG. 8B, the substrate 140, the first superconductive layer 131, the oxide layer 132, and the second superconductive layer 133 are not etched due to the mask 150. As shown in FIG. 8C, after the etching operation is completed, the mask 150 is removed.

FIGS. 9A to 9C show a sequence of cross-sectional views taken along lines C1-C1′ (region S3) of FIGS. 6D to 6F, respectively.

As shown in FIG. 9A, etching is performed on the third region S3 of the substrate 140 in a direction perpendicular to the substrate 140. The etchant passes through the holes H and, in region S3, isotropically etches the substrate 140, the first superconductive layer 131, the oxide layer 132, and the second superconductive layer 133.

As shown in FIG. 9B, after the etching, the first superconductive layer 131 and the oxide layer 132 have been etched away in the third region S3 due to the corresponding holes in the mask 150 arranged on the portions of the substrate 140 and the second superconductive layer 133.

As also shown in FIG. 9B, some of the thickness (in the Z direction) of the second superconductive layer 133 may also be etched away. In addition, the X-direction width of the mask 150 on the second superconductive layer 133 may be greater than an X-direction width of the second superconductive layer 133 (i.e., the mask overhangs the layer). A portion of the substrate 140 exposed by the holes H may also be etched to form a second trench T2 in the substrate 140 (in the third region S3). As shown in FIG. 9C, after the etching operation is completed the mask 150 is removed.

To summarize, FIGS. 6A-9C show a process of isotropic etching around the junction of a Josephson juncture using a mask with holes in the third region S3. Having only the first conductive layer in the first region S1 may be achieved by initially etching the top two layers (second superconductive layer 133 and oxide layer 132) in region S1. Regions S1 and S2 may be masked, and mask holes in region S3 may allow the bottom two layers (oxide layer 132 and first superconductive layer 131) in region S3 to be undercut with isotropic etching. As will become apparent with the description of FIGS. 10A to 13C, with some slight changes in the mask, the same general manufacture process may be used with anisotropic etching.

FIGS. 10A and 10B illustrate a portion of a method of manufacturing a Josephson junction device, according to one or more embodiments. The method of FIGS. 10A and 10B may involve anisotropic etching rather than isotropic etching. Before the processes of FIGS. 10A to 10B, the processes described with reference to FIGS. 6A to 6D may be performed. In FIGS. 10A to 10B, the same reference numerals as those in FIGS. 2A and 2B denote identical members. However, in this embodiment, the workpiece of 6A is not etched to remove the top two layers in region S1.

FIGS. 10A to 10B show a manufacturing method using anisotropic etching.

Referring to FIG. 10A, Regions S1 and S2, where various portions of the sandwich of first superconductive layer 131, the oxide layer 132, and the second superconductive layer 133 are to be maintained, is masked. In region S3, hole H is provided to allow etching in that region. Specifically, the anisotropic etching through the hole H may undercut (and remove) the first superconductive layer 131 and the oxide layer 132 (not shown) in region S3. The stability of the oxide layer 132 in the second region S2 may be secured through the use of a dry etching process using the mask 150. The first superconductive layer 131 and the oxide layer 132 may thus wise be etched away in the third region S3.

In the etching of the first superconductive layer 131 and the oxide layer 132 in region S3 (not shown), part of the second superconductive layer 133 in region S3 may also be etched (its thickness in the Z direction may be reduced). The second superconductive layer 133 may have a sufficient initial thickness to maintain superconductivity despite this reduced thickness.

Referring to FIG. 10B, after etching the portions of the first superconductive layer 131 and the oxide layer 132 (not shown), portions of the substrate 140 may also be etched. In region S1, two trenches T1 may have been previously formed in the substrate 140 during the patterning step described above (see FIGS. 6B and 6C). In region S3, a second trench T2 may be formed in the substrate 140. Unlike FIG. 6E, the first superconductive layer 131 and the oxide layer 132 (not shown) in region S3 are etched away by using anisotropic etching. That is, some of the first superconductive layer 131 and the oxide layer 132 in region S3 may be etched with anisotropic etching from a first direction, and then the rest of the first superconductive layer 131 and the oxide layer (not shown) in region S3 may be removed by anisotropic etching from a second direction different from the first direction.

As shown in FIG. 10B, after the anisotropic etching is completed, the mask 150 is removed. The removal of the mask 150 may be made by an etchant that reacts only with the mask 150. Additionally, the portion where the mask 150 is removed may be cleaned after removing the mask 150, which may improve the performance of the Josephson junction device.

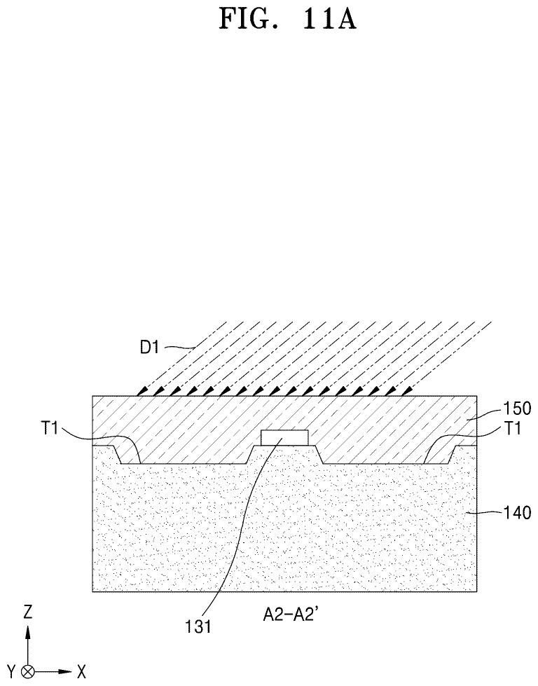

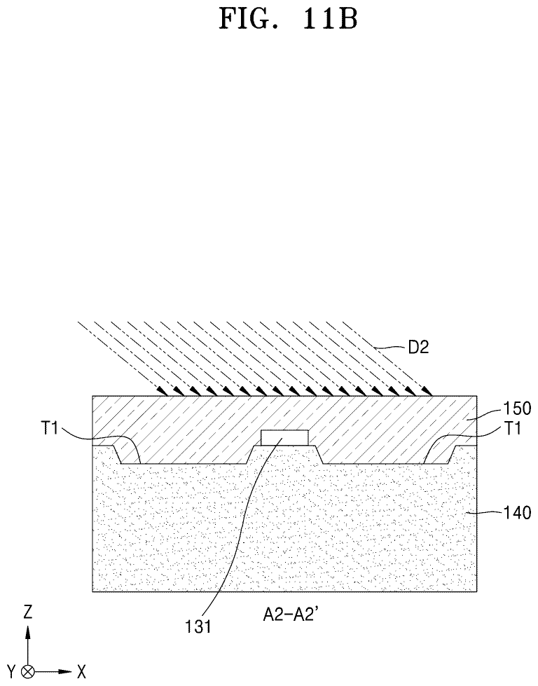

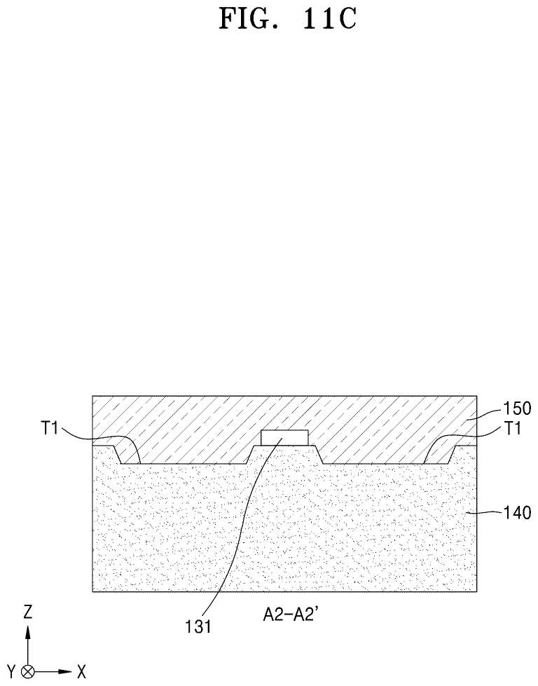

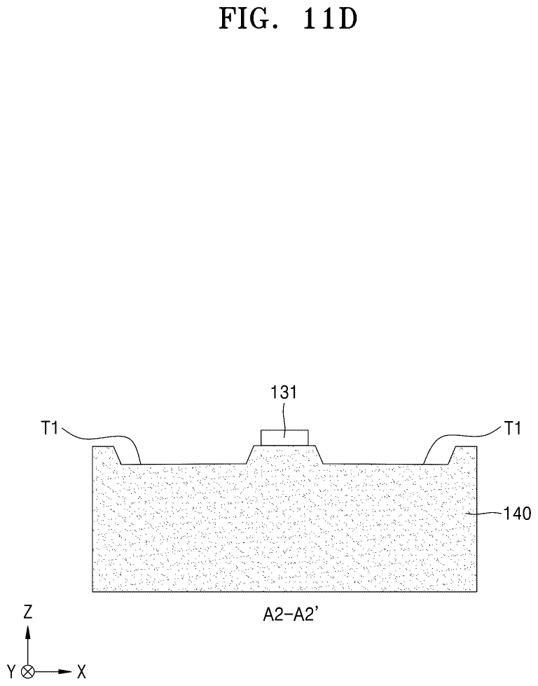

FIGS. 11A-11D, 12A-12D, and 13A-13D show sequences cross-sections of regions S1, S2, and S3, respectively during anisotropic etching of FIGS. 10A and 10B. The etching depicted in these figures may all occur at the same time as part of the same anisotropic etching operation.

FIGS. 11A to 11D show a sequence of cross-sectional views taken along lines A2-A2′ (first region S1) of FIGS. 10A and 10B.

Referring to FIG. 11A, etching is performed in the first region S1 in the first direction D1 having a predetermined angle to the plane of the substrate 140. As shown in FIG. 11B, etching is then performed in the second direction D2 having a predetermined angle to the plane of the substrate 140. The first direction D1 and the second direction D2 may be symmetrical (mirrored) with respect to a normal of the substrate 140. As shown in FIG. 11C, in region S1, due to the mask 150, the substrate 140 and the first superconductive layer 131 are preserved. In addition, as shown in FIG. 11C, trenches T1 may have been previously formed next to the first superconductive layer 131 by the patterning step (see FIGS. 6B and 6C). As shown in FIG. 11D, after the etching is completed the mask 150 is removed.

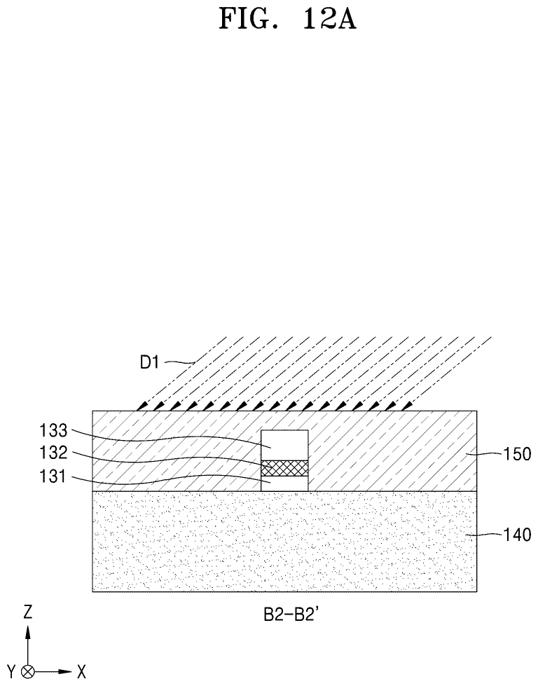

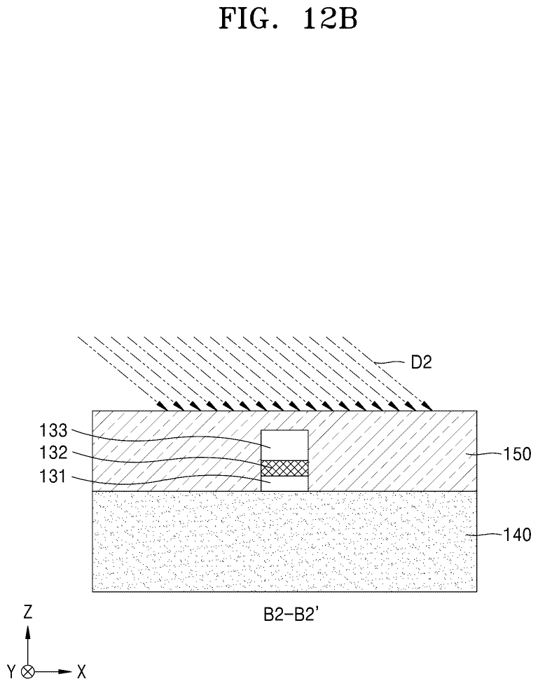

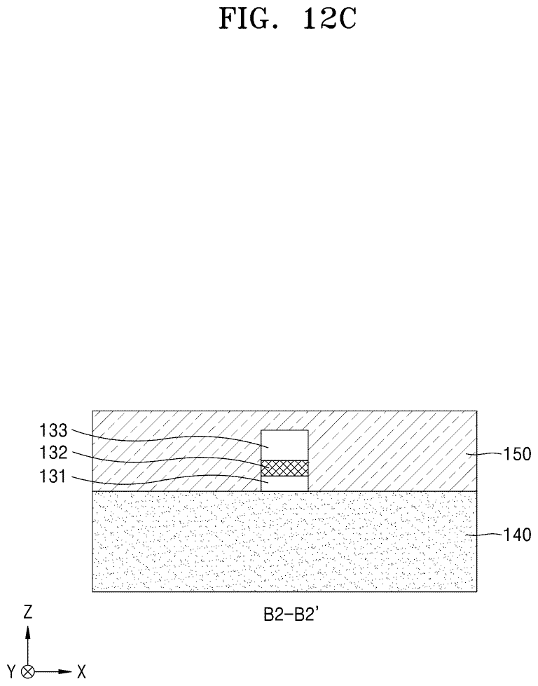

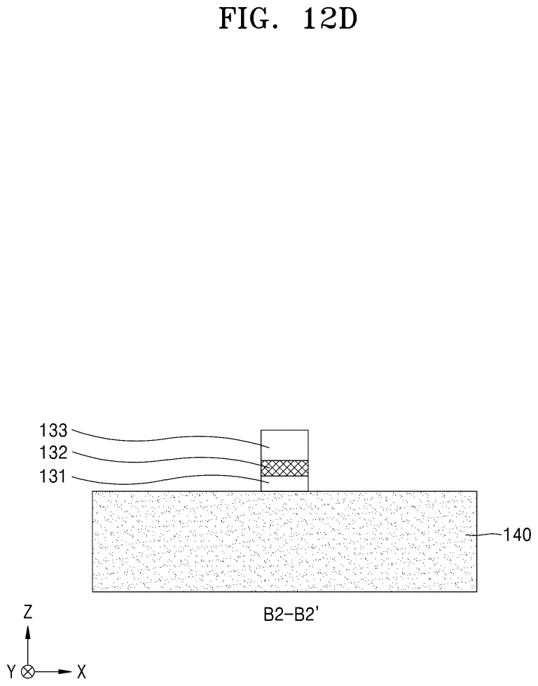

FIGS. 12A to 12D are cross-sectional views taken along lines B2-B2′ (second region S2) of FIGS. 10A and 10B.

Referring to FIG. 12A, etching is performed in the second region S2 in the first direction D1. As shown in FIG. 12B, etching is then performed in the second direction D2. As shown in FIG. 12C, the substrate 140, the first superconductive layer 131, the oxide layer 132, and the second superconductive layer 133 are not etched due to the mask 150. As shown in FIG. 12D, after the etching is completed the mask 150 is removed.

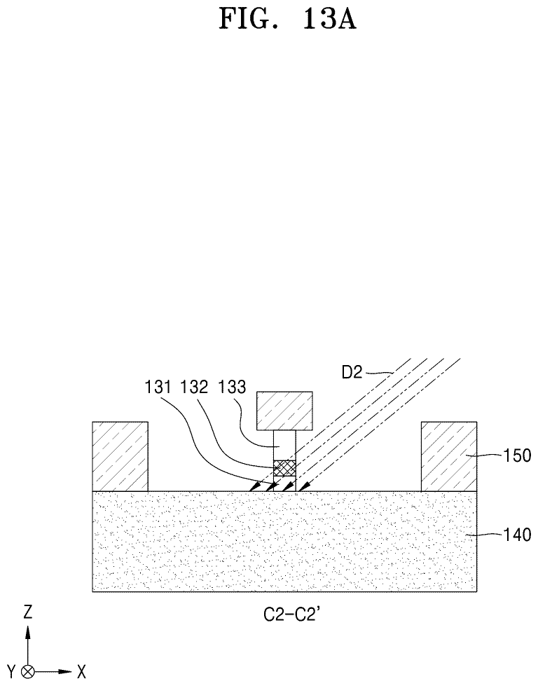

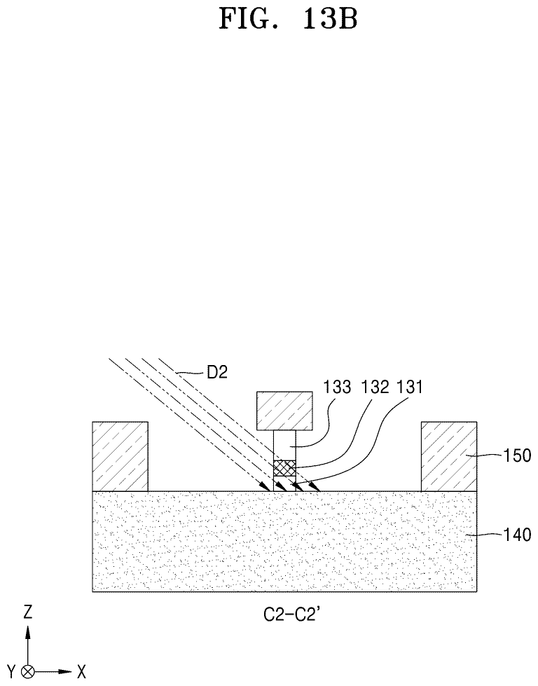

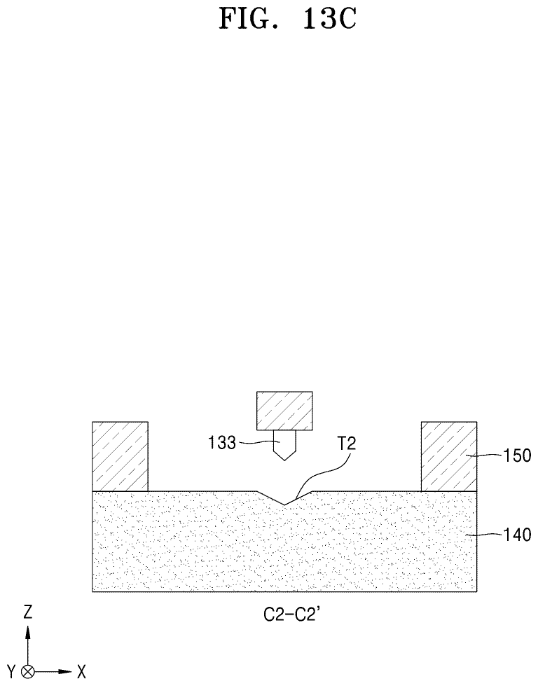

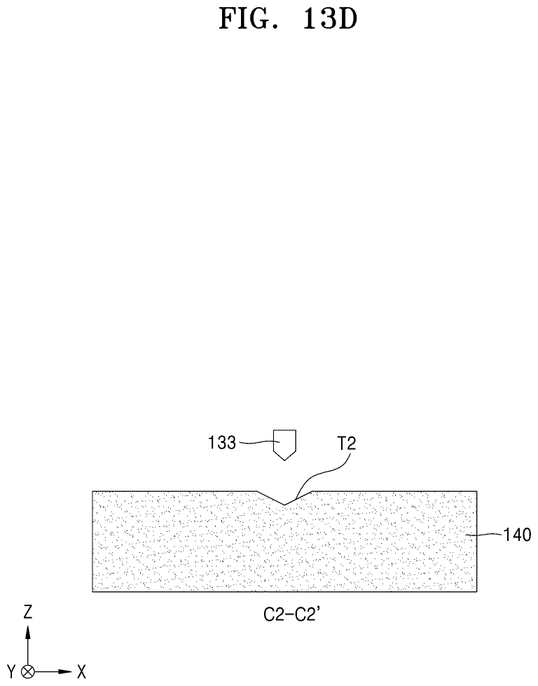

FIGS. 13A to 13D show a sequence of cross-sectional views taken along lines C2-C2′ (third region S3) of FIGS. 10A and 10B.

Referring to FIG. 13A, the anisotropic etching is performed in the third region S3 in the first direction D1 through the hole H. As shown in FIG. 13B, then the anisotropic etching is performed in the second direction D2.

As shown in FIG. 13C, the first superconductive layer 131 and the oxide layer 132 in the third region S3 have been etched away (removed) due to the mask 150 arranged on the portions of the substrate 140 and the second superconductive layer 133 (sides of holes H). A portion (but not all) of the second superconductive layer 133 in third region S3 has also been etched away, as seen with its peaked profile. In this case, the X-direction width of the mask 150 on the second superconductive layer 133 is greater than the X-direction width of the second superconductive layer 133. A portion of the substrate 140 has also been etched away. Although not shown in FIG. 13C, a small portion of the substrate 140 may be etched to form a second trench T2 in the substrate 140 (in the third region S3). As shown in FIG. 13D, after the etching is completed, the mask 150 is removed.

The technique of FIGS. 10A-13D may also be performed with isotropic etching (e.g., dry etching) as described with reference to FIGS. 7A to 9C, although some minor adjustments of the mask hole may be needed to attain the desired structure.

The Josephson junction device and the Josephson junction device manufacturing method may secure stability of an oxide layer that serves as the thin film insulator at the junction, enable a fine/precise process, and be compatible with an existing foundry process. The semiconductor device and the method of manufacturing the same have been described with reference to embodiments shown in the drawings. The Josephson junction device manufacturing method according to the disclosed embodiment may secure stability of an oxide layer and reduce process errors.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A Josephson junction device having a second region between the first and third regions, the Josephson junction device comprising:
a substrate in the first, second, and third regions;
a first superconductive layer arranged on the substrate in the first and second regions and not the third region;
a second superconductive layer arranged in the second and third regions and spatially overlapping the first superconductive layer in the second region;
an oxide layer sandwiched between the first superconductive layer the second superconductive in the second region; and
a first trench in the substrate in the third region, the trench passing under the second superconductive layer in the third region.

2. The Josephson junction device of claim 1, wherein in between the first region and the second region there is a step in the substrate.

3. The Josephson junction device of claim 1, wherein the first region has the first superconductive layer therein, but not the oxide layer and the second superconductive layer.

4. The Josephson junction device of claim 3, wherein the third region has the second superconductive layer therein, but not the first superconductive layer and the oxide layer.

5. The Josephson junction device of claim 1, wherein each of the first superconductive layer and the second superconductive layer independently comprises aluminum (Al), neobium (Nb), indium (In), alpha-tantalum (α-Ta), titanium (Ti), lead (Pb), vanadium (V), or a compound thereof.

6. The Josephson junction device of claim 1, wherein the oxide layer comprises aluminum oxide, neobium oxide, or alpha-tantalum (α-Ta) oxide.

7. A method of manufacturing a Josephson junction device having a substrate in a first region, a third region, and a second region between the first and second regions, the method comprising:
in the first, second, and third regions, forming a first superconductive layer on the substrate;
in the first, second, and third regions, forming an oxide layer on the first superconductive layer;
in the first, second, and third regions, forming a second superconductive layer on the oxide layer;
in the first region, performing an etching process to remove the oxide layer and the second superconductive layer therein while maintaining at least some of the first superconductive layer therein;
forming a mask on the first superconductive layer in the first region and on the second superconductive layer in the second and third regions; and
using the mask, removing, by the etching process, from the third region, the first superconductive layer and the oxide layer.

8. The method of claim 7, wherein the etching process in the third region reduces the second superconductive layer in the third region.

9. The method of claim 7, wherein the etching process in the third region forms a trench in the substrate in the third region.

10. The method of claim 7, wherein the etching process includes anisotropic etching in a first direction and anisotropic etching in a second direction.

11. The method of claim 10, wherein the anisotropic etching in the first direction removes a first side of the first conductive layer and the oxide layer in the third region, and wherein the anisotropic etching in the second direction removes a second side of the first conductive layer and the oxide layer in the third region.

12. The method of claim 10, wherein the etching process comprises plasma etching, reactive ion etching, or ion milling.

13. The method of claim 7, wherein the mask comprises a silicon oxide mask, a gallium mask, a chromium mask, or an e-beam mask, wherein,
in the third region, a strip of the mask on the second superconductive layer separates two holes in the mask that allow the etching process, and wherein,
the holes allow the etching process to remove the first superconductive layer and the oxide layer from the third region.

14. The method of claim 7, further comprising:
after the etching process, removing the mask; and
cleaning a portion of the Josephson junction device where the mask has been removed.

15. The method of claim 7, wherein the mask does not cover a portion of the third region.

16. The method of claim 7, wherein each of the first superconductive layer and the second superconductive layer independently comprises aluminum (Al), neobium (Nb), indium (In), alpha-tantalum (α-Ta), titanium (Ti), lead (Pb), vanadium (V), or a compound thereof.

17. A method of producing a Josephson junction device having a second region between first and third regions, the method comprising:
in first, second, and third regions, forming a first superconductive layer on a substrate;
in at least the second and third regions, forming an oxide layer on the first superconductive layer and forming a second superconductive layer on the oxide layer;
forming a mask covering the second region and only parts of the third region; and
performing an etching process that
removes the first superconductive layer and the oxide layer from the third region, and
preserves at least some of the second superconductive layer in the third region.

18. The method of claim 17, wherein the etching process comprises dry anisotropic etching performed at two different angles, relative to a plane of the substrate.

19. The method of claim 17, wherein the etching process comprises dry isotropic etching.

20. The method of claim 17, further comprising:
in the first region, forming the oxide layer and the second superconducting layer.
